(19) United States
(12) Patent Application Publication
(10) Pub. No.: US 2011/0247682 A1
(43) Pub. Date: Oct. 13, 2011

(54) Solar Balls: Solar Collection System for Any Climate

(75) Inventors: Brent Harper, Mazomanie, WI (US); Thomas Mackie, Verona, WI (US); Tim Holzmann, Verona, WI (US)

(73) Assignee: Solar Foundries, LLC, Verona, WI (US)

(21) Appl. No.: 13/083,234

(22) Filed: Apr. 8, 2011

Related U.S. Application Data
(60) Provisional application No. 61/342,073, filed on Apr. 9, 2010.

(51) Int. Cl. H01L 31/048; H01L 31/0232

(52) U.S. Cl. 136/251; 136/259

(57) ABSTRACT

The energy crisis that has long been accepted in the scientific community is being embraced by society along with an increasing sense of environmental responsibility. Solar will be a large part of the renewable energy revolution. Solar harnessing technology has primarily focused on solar farms or on off-grid, residential use and mostly on warm, dry climates that have high percentages of clear sky. Cooler, wetter climates have seen less research and resources dedicated to solutions and indeed have a different set of requirements than for traditional desert solar farms. This invention provides a simple tracking solar solution that combines both concentrated photovoltaic CPV and traditional photovoltaic (PV), although the solution can use only CPV or PV. The invention reduces the structural and drive demands by shielding the solar collecting mechanisms inside an enclosure and then connecting the collecting mechanisms in synchronous arrays. By shielding the collecting mechanisms from moisture and wind, the drive and support mechanisms can be very simple and inexpensive. The use of both CPV and PV increases the efficiency, particularly in cooler climates.

This patent application claims the filing date from the provisional patent filed Apr. 9, 2010 and assigned Ser. No. 61342073.

### FIELD OF THE INVENTION

The invention relates to a system for collecting solar radiation. The system tracks the sun, focuses the sunlight, and shields the focusing mechanism from wind and precipitation.

### BACKGROUND

The world is moving toward renewable energy. Developed countries are attempting to reduce dependence on fossil fuels and developing countries want point-of-use electrical power generation so they can avoid the high costs of a power grid infrastructure. Solar is the leading candidate for global renewable energy, but it is currently hampered by poor return-on-investment for most locations in the world. An inexpensive, scalable solar collection technology that tracks would open solar energy to most of the populated world.

There are three primary types of solar conversion technologies: large-area photovoltaic (PV), concentrated photovoltaic (CPV), and concentrated thermal (CT). Photovoltaic are arrays of cells that contain solid-state material that converts solar electromagnetic waves into direct current (DC) electricity.

Concentrated photovoltaic cells use a focusing system to concentrate solar radiation onto a solid-state (semiconductor) converter. The focusing mechanism must track the sun in order to concentrate the radiation onto the collector. CPVs operate most effectively in sunny weather since clouds and overcast conditions create diffuse light, which essentially cannot be concentrated efficiently. Commercial CPV semiconductors are approaching 40% conversion efficiency.

Large-area PV is the most commonly implemented solar conversion technology. It can convert diffuse and direct sunlight. Most often PV is fixed. This eliminates the costs associated with tracking but reduces the sunlight that can be converted. It also requires a large area of processed semiconductor that increases the cost.

Concentrated thermal uses a tracking system to concentrate the solar radiation just as CPV does. But the CT solution uses the solar radiation to produce heat and then processes the thermal energy instead of producing DC electric energy directly as with CPV and PV. CT involves two thermal conversion processes and this limits the overall efficiency of CT. Thermal solutions can also be problematic in climates where the temperature drops below freezing.

Solar energy collection has typically been implemented in two forms: large, tracking systems in the warm, arid climates near the tropics or in fixed, flat-panel systems in off-grid applications. Tracking systems have far superior efficiencies per square meter of collection area when compared to fixed, flat-panel systems. The reasons are two-fold. The first is that the CPV conversion sensors are much more efficient than large-area PV sensors. The second reason is based in trigonometry and planetary physics. A full, two-axis tracking system can collect around 1.8 times the energy as a fixed system for the same area of coverage.

Tracking systems are more complicated and expensive than fixed systems. The collector system has to be supported and the entire system has to move in one- or two-dimensions. The support and movement costs are increased when the system usually must resist wind, rain, snow, ice, and freezing temperatures. The cost is further increased by the service costs associated with systems that have moving parts. The tracking, concentrator system can focus on a compact photovoltaic module or on a thermal system.

Another aspect of the solar market is the electrical grid. Off-grid solar applications have to include energy storage and take into account worst-case scenarios. On-grid solar applications may supplement or even sell power back to the utilities. Residential, streetlights, and remote telecom applications are generally willing to sacrifice some efficiency for reliability and lower installation costs. This usually means no moving parts and that means a fixed, PV solution. A reliable tracking system could compete with fixed-panel solutions as the size could be reduced due to the improved efficiencies.

Solar collection farms put a premium on return-on-investment. Efficiency is paramount for this application so tracking, CPV solutions dominate. The number of clear sky days and annual incident radiation figure prominently in the location of such solar collection farms. The initial cost of installation and maintenance also figure heavily so most solar collection farms are located in warm, dry climates and are close to the tropics.

The process of invention follows repeated attempts to satisfy the requirements and constraints of the problem. The process also often includes the establishment of the requirements and constraints themselves. The requirements for this invention which is a solar collection for any climate include: safe and functional operation in icy, rainy, snowy, and high-wind conditions; reasonable payback which includes ease and cost of manufacture, reliability, cost of installation, cost of energy conversion and storage, and efficiency; reliability which includes the number of moving parts, size, number of cantilevered parts, stresses and torques even at high wind velocities or under snow and ice loads; be easy to install, easy to service, operate quietly and safely, and be visually appealing; be environmentally friendly which includes local wildlife; full, two-axis tracking of the sun; and return-on-investment must not be affected significantly by the tracking system.

An effective solar collection solution for any climate hinges on an inexpensive tracking mechanism. The first step to a solution is to identify what affects the cost of the tracking mechanism and then reduce or eliminate those factors. It is primarily the elements that increase the cost of tracking mechanisms: wind, rain, snow, ice, and even sunlight. Focusing lenses, reflectors, or troughs have to withstand dynamic forces from wind and the freezing/thawing cycle. The structural supports not only cost money, they add weight, which then demand larger motors and additional support for tracking under the different environmental load conditions.

The actual focusing mechanism could be made rather cheaply if it only needed to support it's own weight. It would follow that the tracking mechanism would also be rather inexpensive, as it would have to drive only small masses under consistent forces. The solution should reduce or eliminate the elements (except for sunlight of course) from the focusing mechanism.

There are systems that exist which put a ‘lid’ on a trough. But the requirements demand very low forces and operation in snow and ice. Collection systems must also resist the buildup of snow, ice, and debris. A planar lid must absorb significant and asymmetric forces from wind and can accumulate snow, ice, and other debris.

This invention provides a simple tracking solar solution that combines both concentrated photovoltaic CPV and traditional photovoltaic (PV), although the solution can use only CPV or PV. The invention reduces the structural and drive demands by shielding the solar collecting mechanisms inside an enclosure and then connecting the collecting mechanisms in synchronous arrays. By shielding the collecting mechanisms from moisture and wind, the drive and support mechanisms can be very simple and inexpensive.

### BRIEF DESCRIPTION OF DRAWINGS

FIG. 1. Solar Ball concept with PV and CPV using a reflector system with one internal axis of rotation and one external axis of rotation where the ball is driven locally or linked to external drive mechanisms.

FIG. 2. Solar Ball one-dimensional array

FIG. 3. Solar Ball two-dimensional array

FIG. 4 Boxed, two-dimensional array with two internal axes of rotation for each element

FIG. 5. Boxed, one-dimensional array with two internal axes of rotation for each element showing circular and non-circular focusing geometries.

FIG. 6. Solar Ball with PV and CPV using a reflector system for focusing and utilizing two internal axes of rotation.

FIG. 7. Solar Ball with PV and CPV using a reflector system for focusing and utilizing two external axes of rotation with the focusing lens built into the enclosure.

FIG. 8. Solar Ball using a Fresnel lens for focusing and utilizing one internal axis of rotation and one external axis of rotation with only CPV conversion.

FIG. 9. Solar Ball using a Fresnel lens for focusing and utilizing one internal axis of rotation and one external axis of rotation with CPV and PV conversion.

FIG. 10. Solar Ball with only PV conversion while utilizing one internal axis of rotation and one external axis of rotation.

### DETAILED DESCRIPTION

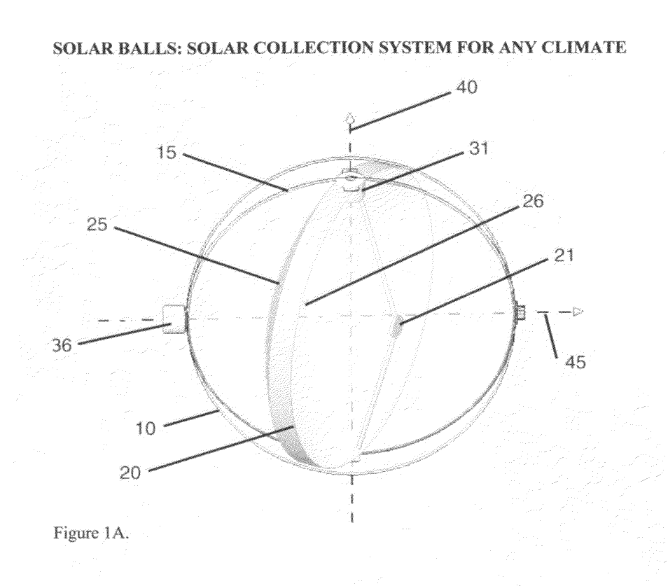

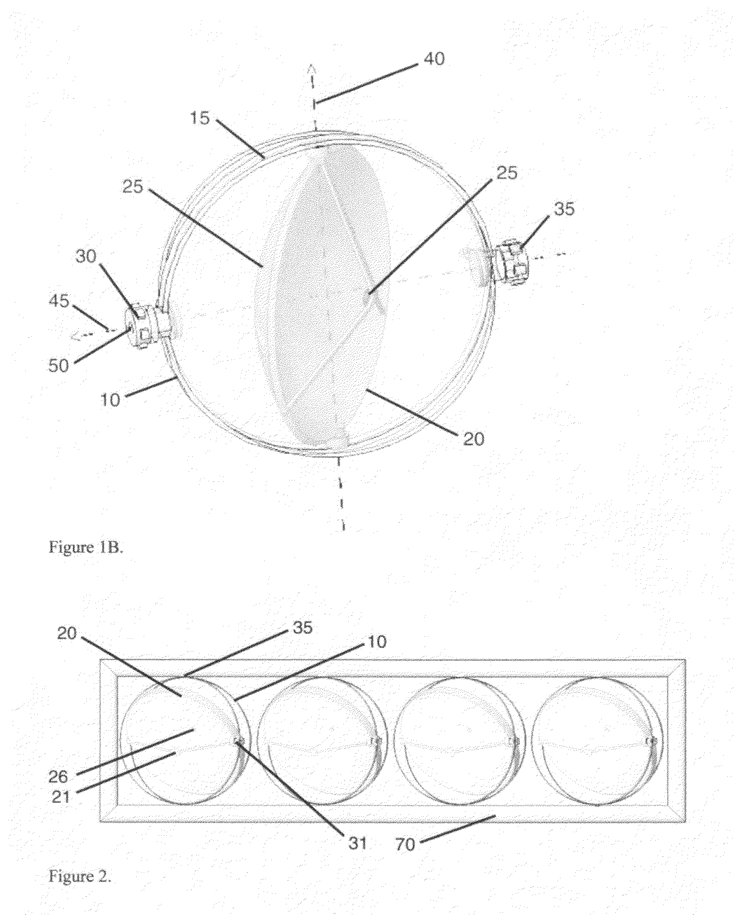

The invention consists of a tracking solar collection system and a protective enclosure. Illustrated in FIG. 1 is an exemplary solarball that includes an enclosure 10 built from two, nearly identical halves and joined at a seam 15. The collection mechanism consists of reflecting focusing mechanisms 20,21, a CPV module 26, and optional PV 25. This configuration utilizes one rotational axis 40 between the collection mechanism and the enclosure that is driven locally by a motor and gearing 31 mounted to the collection mechanism. The second rotational axis 45 is between the enclosure and the mounting structure and is driven locally by a motor and gearing 36. FIG. 1B also utilizes one internal axis of rotation 40 and one external axis of rotation 45, but they are both driven by external linkages 30, 35 instead of local motors and gearing. This configuration allows the solar balls to be linked and driven simultaneously and also shows a thermal port 50 that may be used for heat transfer and moisture management. This configuration also uses a single focusing reflector 20 instead of two focusing reflectors.

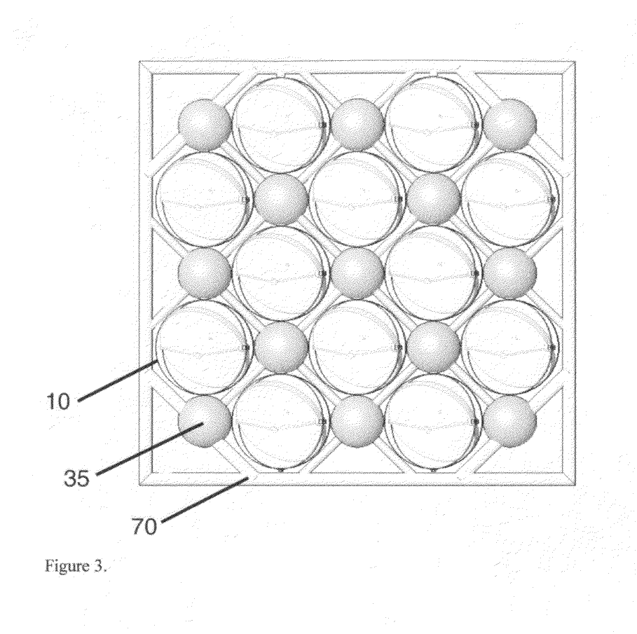

Solar balls can be implemented individually or in arrays. FIG. 2 shows a one-dimensional array of solar balls. The balls are mounted in a frame 70. The rotational axes may be driven individually by motors and gears or linked together and driven synchronously. FIG. 3 shows a two-dimensional array of solar balls including the mounting frame 70, solar ball enclosures 10, and drive linkages 35.

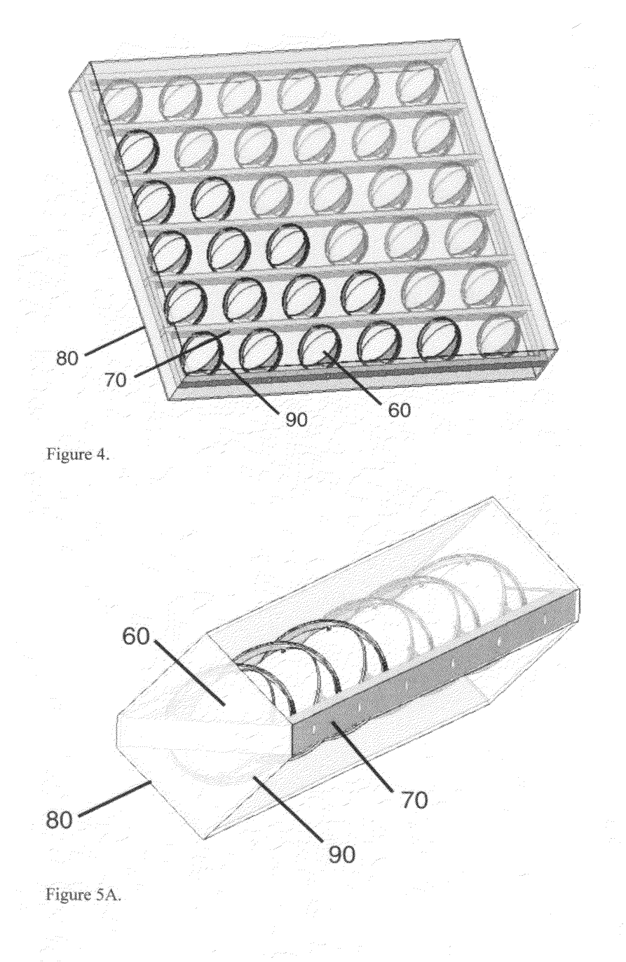

The tracking collectors can be individually housed in enclosures and then built into arrays or they can be built into arrays and then placed into larger enclosures. FIGS. 4 and 5 show two-dimensional and one-dimensional arrays of solarballs including a mounting frame 70, arrays of focusing solar mechanisms that utilize two internal axes of rotations, and are housed in a single enclosure 80. These figures use circular Fresnel lenses 60 and internal linkage and support mechanisms 90. These two configurations can use focusing mechanisms other than circular. FIG. 5B shows square Fresnel lenses 65 in a one-dimensional array.

There are three configurations for the focusing mechanisms that vary depending upon the locations of the two axes of rotation. The enclosure for the configurations that have a single solar collection mechanism inside should be a sphere or ellipsoid. These shapes ensure that the wind load can be minimized while allowing the drive mechanism to rotate the ellipsoid with the minimum torque, even while it is under wind or other environmental loads. The focusing mechanism, PV 25 and/or CPV 26 are contained entirely within the ellipsoid. They are completely protected from all of the elements except for sunlight. The protective ellipsoid allows the internal mechanicals to be very lightweight and inexpensive. The ellipsoid may rotate on zero, one, or two axes with respect to the mounting structure. FIGS. 1, 8, 9 and 10 illustrate the first configuration where the enclosure 10 rotates with respect to the frame and the entire internal solar collection mechanism rotates on an axis 40 that is orthogonal to the ellipsoid's first axis of rotation 45.

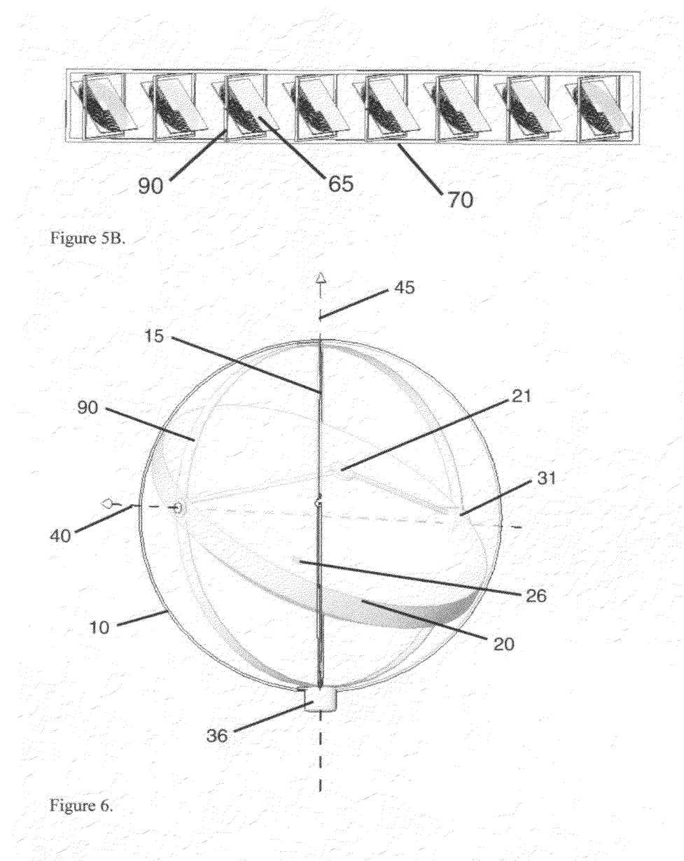

FIG. 6 illustrates a configuration where both axes of rotation 40, 45 are internal to the enclosure with the enclosure being fixed to the mounting structure. An internal linkage 90 rotates on an axis 45 with respect to the enclosure and the solar collection mechanism 20, 21, 26 rotates on an axis 40 that is orthogonal to the internal linkage's first axis of rotation 45.

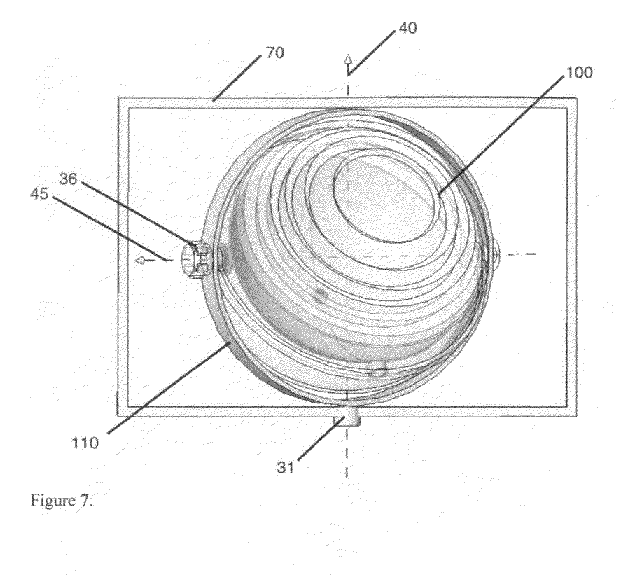

FIG. 7 illustrates a configuration where the internal solar collection mechanism is fixed to the enclosure and where both axes of rotation 40, 45 between the enclosure and the mounting structure 70. The first axis 45 is between the ellipsoidal enclosure 10 and the external linkage 110 with drive mechanism 36 and the second axis 40 with drive mechanism 31 is orthogonal to the first and is between the external linkage 110 and the frame 70. The solar collection enclosure may have a Fresnel lens formed into it 100.

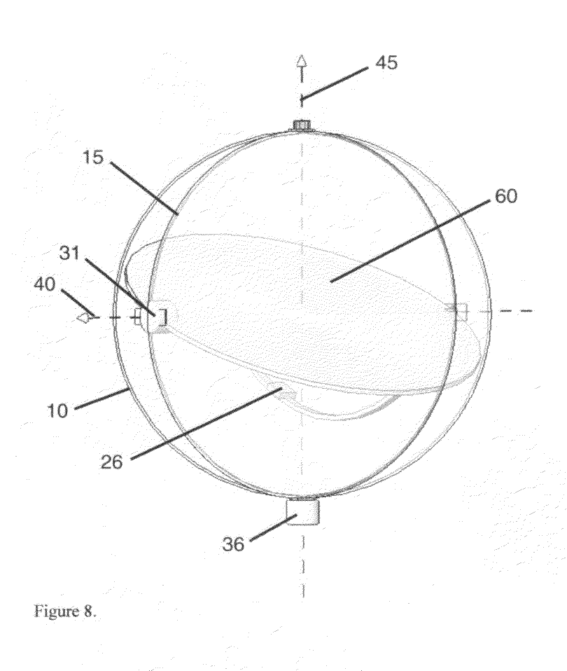

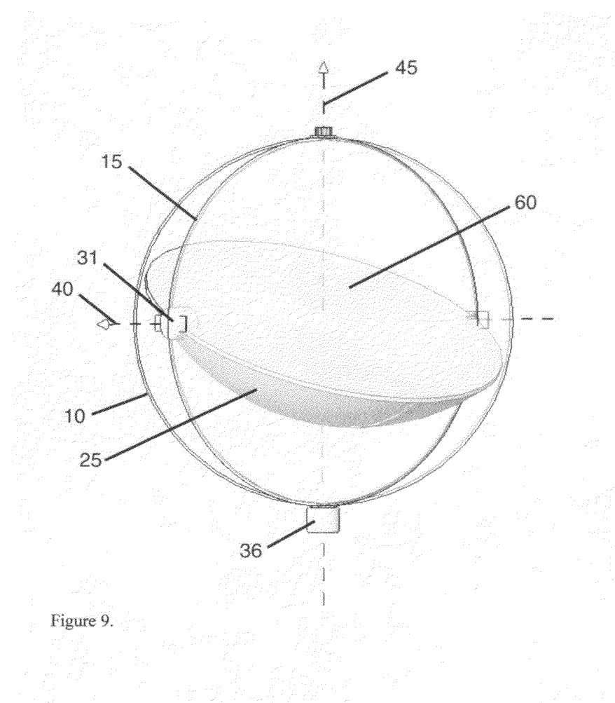

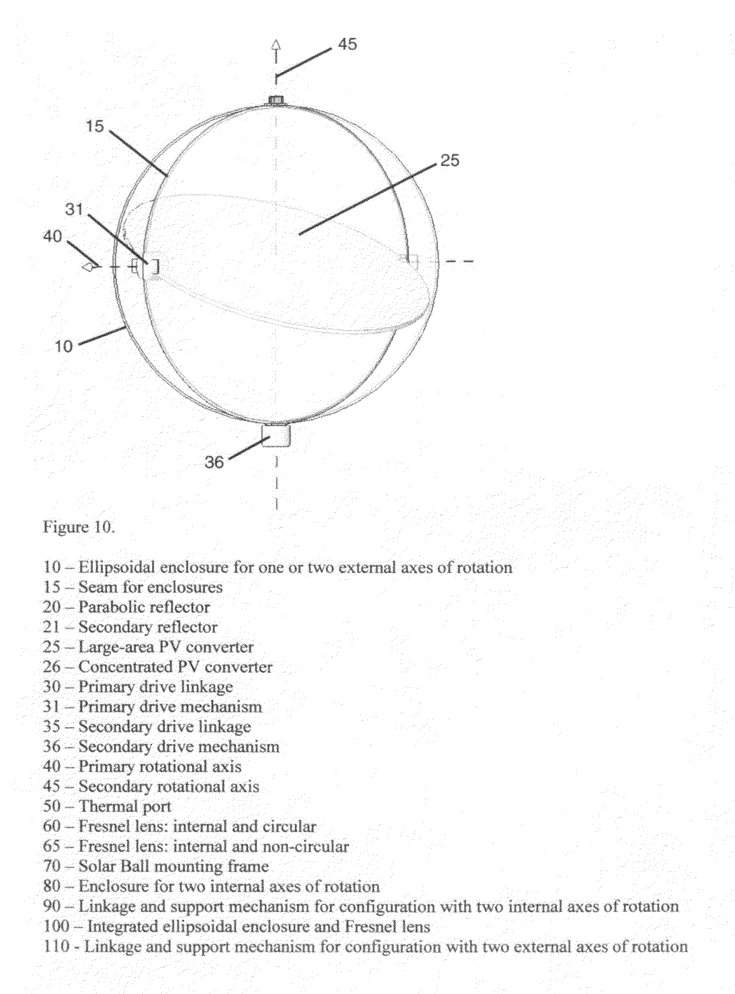

The solar collection mechanism may take many forms. The conversion may be accomplished with large-area PV 25 or CPV 26. For CPV the focusing mechanism may be a single reflector, several reflectors, a lens or a Fresnel lens. FIGS. 8, 9, and 10 show three additional configurations of conversion mechanisms while all use one internal and one external axis of rotation. FIG. 8 uses only CPV 26 for conversion with a circular Fresnel lens 60. FIG. 9 uses both CPV 26 and PV 25 and utilizes a circular Fresnel lens 60 for the CPV conversion mode. FIG. 10 uses only PV 25.

The preferred shape of the ellipsoid enclosure is actually a sphere or ball.

The ability to rotate the entire, symmetric enclosure also provides a simple mechanism for cleaning off any debris or snow that might begin to accumulate. The ellipsoid shape also allows for a fixed scraper to clean the enclosure as it rotates if the environment requires this additional mechanism.

Solar balls provide a variety of benefits. The balls can be used individually or in arrays. Individual balls could be mounted to light poles or telecommunication boxes or even as lawn fixtures. Arrays can be coupled and driven by a single motor for each axis or may be driven individually. Furthermore, the arrays can be mounted to independent structures that can be raised above any surface. The full, two-axes motions would allow the arrays to be mounted horizontally, vertically, or at an angle. This means that they could be mounted on walls, commercial buildings that have flat rooftops, houses that have pitched rooftops, or even on pergolas above parking lots.

The configuration that has both axes of rotation internal to the enclosure may be made into an array of tracking collectors that are placed inside a single enclosure 80. Here the axes of rotation do not require an ellipsoid enclosure, but rather simple mechanical supports. The structure must still satisfy all of the requirements including resisting the elements except for sunlight while not allowing the buildup of debris, ice, or snow. The enclosure is essentially a thin box for a two-dimensional array or a peaked box for a one-dimensional array.

The two-dimensional array box must be oriented in a primarily vertical fashion to ensure that debris, ice, and snow will not accumulate. The box must be transparent on at least one side but may be transparent on all sides. The box must be able to withstand all other environmental forces including wind, fauna, freezing, snow, ice, UV, and rain.

The one-dimensional array box must be oriented so that snow and debris would fall off. The geometry here includes a host of possibilities including a tented structure. As with all of the solar collection arrays, the two axes of all of the collection cells are driven in synch by common motors.

CPV usually provides the best cost performance for tracking systems. This analysis has typically been done for warm, dry solar farms. Solar balls provide a unique opportunity to merge PV and CPV. The internal focusing structure could be constructed with a PV collector on the backside. The additional cost is limited to the PV material itself as all of the mechanicals and wiring already exist for the CPV. The solar ball would then sense the intensity of the incident light which varies with cloud cover and flip to optimize collection. The modest increase in cost will be recovered quickly in areas that see significant cloud cover.

The CPV solution requires tracking and focusing of the incident sunlight. There are several focusing solutions that are possible. The focusing can be accomplished with parabolic reflecting mirrors or Fresnel lenses. The preferred reflecting method uses two reflectors, an approximately parabolic reflector and a smaller, secondary reflector. This allows the CPV module to be mounted on or near the main parabolic reflector. This keeps the CPV module and its heat sink from eclipsing the incident sunlight.

The solar collectors can be linked together in arrays. They all need to track the sun so they can be driven synchronously. The system requires only two drive mechanisms for the entire array, one for each axis. The lack of environmental forces allows the tracking mechanism to be lightweight and the drive mechanisms to be small, inexpensive, and reliable. The drive mechanisms also do not require significant accuracy as compared to most motion control applications. A simple actuator system may be used.

Within thermal management are three primary considerations: thermal expansion, photovoltaic efficiency, and condensation. Thermal expansion is not a significant issue with these designs. The relatively small size and mass, coupled with the lack of required rigidity, virtually eliminate thermal expansion concerns.

Photovoltaic efficiency is a huge concern for solar collection farms and a primary factor in system payback calculations. CPV is much more efficient than PV but both operate more efficiently at lower temperatures. Heating issues are compounded by the energy inherent in the solar radiation that is the focus of the collection system. But for most PV, the efficiency suffers only a few percent for temperature deltas of tens of degrees Celsius. In addition, most climates see significant overcast conditions that produce much less heating and unlike most solar collection farms, solar balls are designed to operate in any climate including cool climates.

The photovoltaic cells produce heat during their conversion. While it is not necessary for solar balls to include a thermal management system, the system can have one. There are several methods that would provide a mechanism to remove heat or to cool the PV. The enclosures may include a double-sided heat sink or have thermal ports 50 to remove heat. The solutions can include forced air or even be partially evacuated. The ellipsoid solutions would have holes in the drive pivot mechanisms and the array of enclosures would be controlled by a single thermal drive.

Condensation is undesirable from many aspects including additional weight, freezing and thawing, and optical transparency. Forced air, partial evacuation, thermal convection, membranes, valves, or anti-fog coatings can be used to counter condensation. The enclosures may be sealed and filled with an inert gas to reduce or eliminate moisture concerns.

1. A solar collection system that eliminates most environmental forces from the one- or two-dimensional tracking mechanism.

2. The collection system specified in claim 1 that utilizes an ellipsoidal enclosure that shields an internal solar collection mechanism.

3. The collection system specified in claims 1 & 2 that uses an internal Fresnel lens to focus solar radiation onto a concentrated photovoltaic sensor.

4. The collection system specified in claims 1 & 2 that uses an internal parabolic reflector and/or a second reflector to focus solar radiation onto a concentrated photovoltaic sensor.

5. The collection system specified in claims 1 & 2 that uses a large-area photovoltaic to convert solar radiation.

6. The collection system specified in claims 1 & 2 that uses both concentrated PV for clear sky solar conversion and large-area PV for overcast solar conversion. The solar collection mechanism for this embodiment rotates to expose one of the two solar conversion technologies depending upon the intensity of the incident solar radiation.

7. An array of the collection system specified in claims 1 through 6 where each of the two axes of rotation for each element in the array are linked so that two drive mechanisms operate all of the elements synchronously.

8. An array of the collection system specified in claims 1 through 6 where each of the two axes of rotation for each element in the array are driven independently.

9. A solar collection system specified in claims 1 & 2 where the ellipsoidal enclosure provides one axis of rotation with respect to the support structure and the second axis of rotation between the enclosure and the internal solar collection mechanism.

10. The collection system specified in claims 1 & 9 that uses an internal Fresnel lens to focus solar radiation onto a concentrated photovoltaic sensor.

11. The collection system specified in claims 1 & 9 that uses an internal parabolic reflector and/or a second reflector to focus solar radiation onto a concentrated photovoltaic sensor.

12. The collection system specified in claims 1 & 9 that uses a large-area photovoltaic to convert solar radiation.

13. The collection system specified in claims 1 & 9 that uses both concentrated photovoltaic for clear sky solar conversion and large-area photovoltaic for overcast solar conversion. The solar collection mechanism for this embodiment rotates to expose one of the two solar conversion technologies depending upon the intensity of the incident solar radiation.

14. The collection system specified in claims 1 & 9 that implements a sealed enclosure that includes the drive mechanism for the internal axis of rotation.

15. The collection system specified in claims 1 & 2 that utilizes a fixed enclosure that shields an internal solar collection mechanism where both axes of rotation are internal to the enclosure.

16. The collection system specified in claims 1 & 15 that uses an internal Fresnel lens to focus solar radiation onto a concentrated photovoltaic sensor.

17. The collection system specified in claims 1 & 15 that uses an internal parabolic reflector to focus solar radiation onto a concentrated photovoltaic sensor.

18. The collection system specified in claims 1 & 15 that uses a large-area photovoltaic to convert solar radiation.

19. The collection system specified in claims 1 & 15 that uses both concentrated photovoltaic for clear sky solar conversion and large-area photovoltaic for overcast solar conversion. The solar collection mechanism for this embodiment rotates to expose one of the two solar conversion technologies depending upon the intensity of the incident solar radiation.

20. The collection system specified in claims 1 & 15 that implements a sealed enclosure that includes the drive mechanisms for both of the internal axes of rotation.

21. The collection system specified in claims 1 & 2 that utilizes an enclosure that shields an internal solar collection mechanism where both axes of rotation are between the enclosure and the mounting structure. For this embodiment, the internal solar conversion mechanisms are fixed with respect to the enclosure.

22. The collection system specified in claims 1 & 21 that uses an internal Fresnel lens to focus solar radiation onto a concentrated photovoltaic sensor.

23. The collection system specified in claims 1 & 21 that uses a Fresnel lens to focus solar radiation onto a concentrated photovoltaic sensor where the Fresnel lens is integrated into the enclosure.

24. The collection system specified in claims 1 & 21 that uses an internal parabolic reflector to focus solar radiation onto a concentrated photovoltaic sensor.

25. The embodiment specified in claims 1 & 21 that uses a large-area photovoltaic to convert solar radiation.

26. The embodiment specified in claims 1 & 21 that uses both concentrated photovoltaic for clear sky solar conversion and large-area photovoltaic for overcast solar conversion. The solar collection mechanism for this embodiment rotates to expose one of the two solar conversion technologies depending upon the intensity of the incident solar radiation.

27. The collection system specified in claims 1 & 2 that utilizes an enclosure that shields an internal solar collection mechanism where both axes of rotation are interior to the enclosure and where the enclosure contains multiple solar collection mechanisms.

28. The collection system specified in claims 1 & 28 that uses an internal Fresnel lens to focus solar radiation onto a concentrated photovoltaic sensor.

29. The collection system specified in claims 1 & 28 that uses an internal parabolic reflector to focus solar radiation onto a concentrated photovoltaic sensor.

30. The embodiment specified in claims 1 & 28 that uses a large-area photovoltaic to convert solar radiation.

31. The embodiment specified in claims 1 & 28 that uses both concentrated photovoltaic for clear sky solar conversion and large-area photovoltaic for overcast solar conversion. The solar collection mechanism for this embodiment rotates to expose one of the two solar conversion technologies depending upon the intensity of the incident solar radiation.

32. The embodiment specified in claims 9 & 15 where the enclosure can be rotated to eliminate optically opaque buildup such as snow. The device may include a wire or squeegee to clean debris, ice, or snow from the outside of the enclosure.

33. A method to reduce condensation including anti-fog coatings, forced air, partial evacuation, hermetically sealed and filled, membranes, valves, and thermal convection.
